(19) United States
(12) Patent Application Publication
(10) Pub. No.: US 2024/0184207 A1
(43) Pub. Date: Jun. 6, 2024

(54) EUV PHOTORESIST AND UNDERLAYER ADHESION MODULATION

(71) Applicant: Applied Materials, Inc., Santa Clara, CA (US)

(72) Inventors: Zhiyu Huang, Sunnyvale, CA (US); BOCHENG CAO, Santa Clara, CA (US); SIYU ZHU, Sunnyvale, CA (US); HANG YU, San Jose, CA (US); YUNG-CHEN LIN, Gardena, CA (US); CHI-I LANG, CUPERTINO, CA (US)

(21) Appl. No.: 18/379,106

(22) Filed: Oct. 11, 2023

Related U.S. Application Data
(60) Provisional application No. 63/430,596, filed on Dec. 6, 2022.

(51) Int. Cl. G03F 7/11

(52) U.S. Cl. CPC G03F 7/11

(57) ABSTRACT

Embodiments disclosed herein include a method of developing a patterning stack. In an embodiment, the method comprises providing a patterning stack, where the patterning stack comprises an underlayer and a photoresist over the underlayer, and where the underlayer has a first adhesion strength with the photoresist. The method may further comprise exposing and developing the photoresist with electromagnetic radiation and a developer, where scum remains on a surface of the underlayer. In an embodiment, the method further comprises treating the underlayer so that the underlayer has a second adhesion strength with the scum, and removing the scum.

### CROSS-REFERENCE TO RELATED APPLICATIONS

This application claims the benefit of U.S. Provisional Application No. 63/430,596, filed on Dec. 6, 2022, the entire contents of which are hereby incorporated by reference herein.

### BACKGROUND

### 1) Field

Embodiments of the present disclosure pertain to the field of semiconductor processing and, in particular, to methods of forming a photoresist with an underlayer for adhesion modulation.

### 2) Description of Related Art

Lithography has been used in the semiconductor industry for decades for creating 2D and 3D patterns in microelectronic devices. The lithography process involves spin-on deposition of an underlayer and a film (photoresist) over the underlayer. These spin-on films may include some chemical additives (such as aids) for dose reduction. The process may continue with irradiation of the film with a selected pattern by an energy source (exposure), and removal (etch) of exposed (positive tone) or non-exposed (negative tone) region of the film by dissolving in a solvent. A bake will be carried out to drive off remaining solvent. Spin-on underlayer solutions have some drawbacks, especially with extreme ultraviolet (EUV) lithography operations for smaller pitch features. For example, drawbacks may include composition uniformity and poor adhesion to the photoresist.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), line width roughness (LWR), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process. LER and LWR are stochastic effects during the photolithography. They can be related to, at least in part, to the UV light-material interaction process (such as UV absorption, secondary electron generation, and back exposure from the underlayer), and/or photoresist-underlayer interaction (e.g., adhesion).

### SUMMARY

Embodiments disclosed herein include a method of developing a patterning stack. In an embodiment, the method comprises providing a patterning stack, where the patterning stack comprises an underlayer and a photoresist over the underlayer, and where the underlayer has a first adhesion strength with the photoresist. The method may further comprise exposing and developing the photoresist with electromagnetic radiation and a developer, where scum remains on a surface of the underlayer. In an embodiment, the method further comprises treating the underlayer so that the underlayer has a second adhesion strength with the scum, and removing the scum.

Embodiments disclosed herein may also include a method of patterning a substrate that comprises providing a patterning stack over the substrate. In an embodiment, the patterning stack comprises a first underlayer, a second underlayer over the first underlayer, and a photoresist over the second underlayer. In an embodiment, the method further comprises exposing the patterning stack to electromagnetic radiation, and developing the photoresist in the patterning stack. In an embodiment, the method further comprises modifying the second underlayer so that an adhesion strength to the photoresist is decreased, and removing any scum over the second underlayer.

Embodiments disclosed herein may include a patterning stack. In an embodiment, the patterning stack comprises a first underlayer, and a second underlayer over the first underlayer, where the second underlayer has a thickness that is up to approximately 5 nm, and where the second underlayer has a hydrophobic surface. In an embodiment, the patterning stack may further comprise a photoresist over the second underlayer, where the photoresist has a hydrophobic surface.

### BRIEF DESCRIPTION OF THE DRAWINGS

FIG. 1A is a cross-sectional illustration of a device that includes a photoresist layer that is provided over an adhesion promoting underlayer, in accordance with an embodiment.

FIG. 1B is a cross-sectional illustration of a device that includes a photoresist layer that is provided over a pair of adhesion promoting underlayers, in accordance with an embodiment.

FIG. 2A is a schematic illustration of a device with a photoresist and underlayers, where the chemical bonds between layers are shown, in accordance with an embodiment.

FIG. 2B is a schematic illustration of the device after the photoresist is exposed to electromagnetic radiation, in accordance with an embodiment.

FIG. 2C is a schematic illustration of the device after the photoresist is developed and scum remains over the topmost underlayer, in accordance with an embodiment.

FIG. 2D is a schematic illustration of the device after the underlayers are exposed to a treatment that converts the chemical bonds from hydrophobic to hydrophilic, in accordance with an embodiment.

FIG. 2E is a cross-sectional illustration of the device after the scum is removed, in accordance with an embodiment.

FIG. 3 is a process flow diagram of a process for patterning a photoresist layer that includes a pair of underlayers, in accordance with an embodiment.

FIG. 4A is a schematic illustration of a device that includes a substrate, an underlayer, and a photoresist, in accordance with an embodiment.

FIG. 4B is a schematic illustration of the device after the photoresist is patterned and the underlayer is treated, in accordance with an embodiment.

FIG. 5A is a cross-sectional illustration of a device with an adhesion layer between a photoresist and a low absorption layer, in accordance with an embodiment.

FIG. 5B is a cross-sectional illustration of a device with a low absorption layer under a photoresist, in accordance with an embodiment.

FIG. 6A is a cross-sectional illustration of a device with a multi-layer patterning stack, in accordance with an embodiment.

FIG. 6B is a cross-sectional illustration of a device with a multi-layer patterning stack with an antireflective coating (ARC), in accordance with an embodiment.

FIG. 7 illustrates a block diagram of an exemplary computer system, in accordance with an embodiment of the present disclosure.

### DETAILED DESCRIPTION

Methods of forming a photoresist with an underlayer for adhesion modulation are described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. One type of resist system for EUV lithography is a chemically amplified resist (CAR) system. One drawback of CAR systems is that the CAR-underlayer interface strength (adhesion) is limited. Particularly, the bonding between the two layers is through van der Waals forces. In many instances, high adhesion strength between the photoresist and the underlayer is a desirable property. Strong adhesion strength allows for high aspect ratio features to be formed without the risk of pattern collapse, pattern liftoff, or other patterning defects. High adhesion strength can be provided by tuning an underlayer in order to form strong bonds with the overlying photoresist. The CAR photoresist is typically a hydrophobic material. As such, the underlayer is also formed as a hydrophobic material in order to improve bonding between the two layers.

However, strong adhesion properties can have a negative drawback. For example, when the adhesion strength between layers is strong, it can be difficult to fully remove the exposed photoresist with a developer solution. Unwanted residual photoresist material may sometimes be referred to as scum. The presence of scum over the underlayer can result in patterning defects that are ultimately transferred into the underlayer and substrate. As such, high quality pattern transfer is not possible.

Accordingly, embodiments disclosed herein include an underlayer that is modifiable. As used herein, modifiable layers may be layers that can have their chemical composition changed, or the chemistry of dangling bonds changed. For example, one treatment disclosed herein may convert a hydrophobic material to a hydrophilic material. When the underlayer is hydrophilic, the bond strength between the underlayer and the overlying hydrophobic photoresist is diminished. This allows for scum to be removed easier. In an embodiment, the treatment may include exposing the underlayer to an alkaline solution. The alkaline solution (e.g., approximately 3% tetramethylammonium hydroxide (TMAH) and 97% water) is used during the lithography developing process. Since the alkaline solution already has water, the underlayer does not need to undergo an extra treatment to react with water to form the OH bond. As such, the approach described herein can be easily added to existing lithography processes.

As can be appreciated, there is balance that needs to be struck between having high adhesion strength for patterning, and low adhesion strength for development and removal of scum. Accordingly, some embodiments described herein include a double layer underlayer structure. The first underlayer over the substrate may comprise a material composition that is highly reactive to the treatment, and a second underlayer over the first underlayer may be tuned for adhesion. More particularly, the second underlayer may be thin (e.g., approximately 5 nm or less) and porous. This allows the chemical change to the first underlayer to propagate through the second underlayer in order to modify the interface between the second underlayer and the photoresist.

In other embodiments, a single underlayer is used. The underlayer may comprise an amorphous SiC:H material that is doped. For example, dopants may include Si, Ge, B, or P. In one particular embodiment, a boron dopant may be provided with B₂H₆ that is co-flowed with the SiC:H precursor (e.g., trimethylsilane). The doping elements easily react with water in an alkaline solution to form OH bonds, which converts the surface into a hydrophilic surface. The hydrophilic surface reduces the adhesion strength and enables easier scum removal.

In yet another embodiment, an adhesion layer (e.g., comprising SiCH, SiOC, etc.) may be provided over a low absorption layer. The adhesion layers described herein are formed with CVD/ALD processes which can be easily modulated to control the bulk composition for improved surface bonding. For example, the adhesion layer can be modulated between being Si-rich and C-rich, which is difficult to achieve with spin-on solutions. Though, modulating bulk compositions may not be sufficient in some embodiments to impact surface bonding. As such, additional surface treatments may be needed in order to enhance surface termination (such as —CH₃ terminations). In an embodiment, the low absorption layer is also a CVD/ALD film that can be modulated from Si-rich to C-rich in a similar fashion. However, the low absorption layer serves a different purpose, and may have a different composition than the adhesion layer in order to provide optimal coupling and/or combination of layers. The adhesion layer provides improved coupling with an overlying photoresist layer, while the low absorption layer improves pattern developing. Embodiments disclosed herein may be used in conjunction with the double underlayer approach. For example, the underlayer underneath the thin adhesion layer can react with water to form —OH bonds for the modulation of the adhesion between the CAR and the adhesion promoting layer and/or is a low UV absorption layer which can also reduce the stochastic effects for line roughness (e.g., LER and LWR) and local CD uniformity (LCDU) reduction.

In embodiments disclosed herein photoresist layers are generally described. The photoresist layers may include EUV resist materials such as metal oxo photoresist systems. In other embodiments, the photoresist layers may generally include chemically amplified resists (CARs). The photoresist layers may be suitable for patterning in various electromagnetic radiation, including EUV, deep ultraviolet (DUV), ultraviolet (UV), and the like. More generally, photoresist layers described herein include an electromagnetic radiation sensitive material. The photoresist layers may have a hydrophobic surface provided by chemical bonds, such as CH₃ or the like.

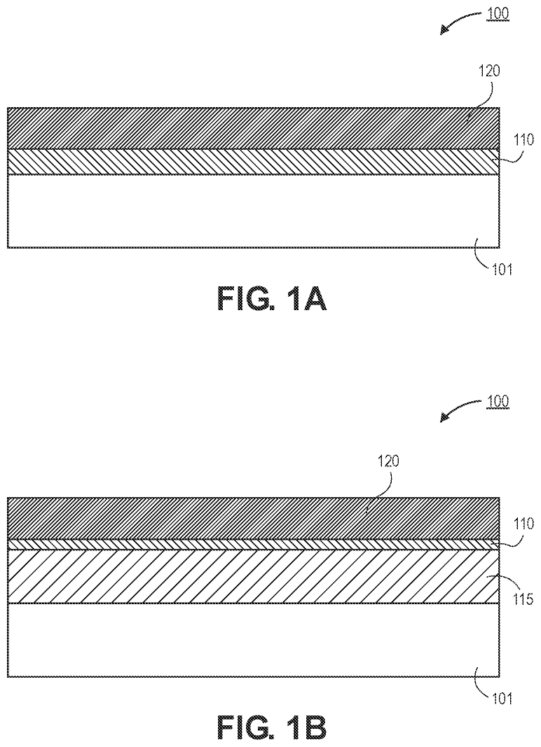

Referring now to FIG. 1A, a cross-sectional illustration of a device 100 is shown, in accordance with an embodiment. The device 100 may comprise a substrate 101. The substrate 101 may comprise a layer that is to be patterned using a lithography process. The substrate 101 may comprise a material that is typically patterned for the formation of structures in a semiconductor device, For example, the substrate 101 may comprise a semiconductor material (e.g., silicon), a metal layer, a dielectric layer, or an insulating layer. In some embodiments, the substrate 101 may also comprise layers that aid in the transfer of a pattern into the substrate 101. For example, the additional layers may include hardmask layers, antireflective coatings (ARCs), and the like.

In an embodiment, the device 100 may further comprise an adhesion promoting layer 110. The adhesion promoting layer 110 may be a material that enables good adhesion strength between the substrate 101 and the overlying photoresist 120. The adhesion promoting layer 110 may have a surface that matches the hydrophobicity of the photoresist 120. Typically, the photoresist 120 is a hydrophobic material with CH₃ dangling bonds. As such, the adhesion promoting layer 110 may also include a hydrophobic surface with CH₃ terminations. One example of such a material is hexamethyldisilazane (HMDS), and another CVD based example is SiC:H or the like. In some embodiments, the adhesion promoting layer 110 may further be doped. For example, dopants such as silicon and boron may be provided in the adhesion promoting layer 110.

The adhesion promoting layer 110 may be a material with a modifiable attraction to water. For example, during exposure and develop of the overlying photoresist 120, the adhesion promoting layer 110 exhibits a strong bond to the photoresist through a hydrophobic interaction. After developing, any residual scum is removed. Removal of scum is made easier when the adhesion between the adhesion promoting layer 110 and the photoresist 120 is decreased. As such, the attraction to water of the adhesion promoting layer 110 may be switched to being hydrophilic. A first material that is hydrophobic (e.g., the photoresist 120) will tend to repel a second material that is hydrophilic (e.g., the modified adhesion promoting layer 110). The adhesion promoting layer 110 may be converted to a hydrophilic surface through application of an alkaline solution. The water may react with the surface to form OH chemical bonds. Accordingly, the scum can be removed more easily from the surface of the adhesion promoting layer 110, which provides a better pattern transfer.

Referring now to FIG. 1B, a cross-sectional illustration of a device 100 is shown, in accordance with an additional embodiment. In an embodiment, the device 100 may comprise a substrate 101. The substrate 101 in FIG. 1B may be substantially similar to the substrate 101 in FIG. 1A. That is, the substrate 101 may include a layer to be patterned (e.g., silicon, metal, dielectric, insulator, etc.), and pattern transfer layers (e.g., hardmasks, ARCs, etc.).

Instead of having a single adhesion promoting layer 110, the device 100 in FIG. 1B may include a dual underlayer solution. A first underlayer 115 may be provided over the substrate 101, and a second underlayer 110 may be provided over the first underlayer 115. The dual underlayer architecture 115/110 may comprise materials suitable for converting the surface between hydrophobic and hydrophilic conditions. In addition to providing a switch between attraction and repulsion to water, the dual underlayer structure 115/110 allows for improved adhesion to the photoresist 120. This is because the second underlayer 110 may be tuned to have high adhesion strength, while the first underlayer 115 can be tuned to be easily convertible to a hydrophilic structure.

In an embodiment, the second underlayer 110 may be a relatively thin layer. For example, the second underlayer 110 may have a thickness that is approximately 10 nm or smaller, or approximately 5 nm or smaller. Additionally, the second underlayer 110 may be a porous material. Due to the small thickness and porosity of the second underlayer 110, the hydrophobic to hydrophilic change in the first underlayer 115 easily propagates through the second underlayer 110. In an embodiment, the first underlayer 115 may comprise materials with Si—H bonds, Si—CH₃ bonds, B—H bonds, and the like. The bonds of the first underlayer 115 may easily convert to OH terminations upon exposure to an alkaline solution including water or the like.

In an embodiment, the first underlayer 115 may have a thickness that is greater than a thickness of the second underlayer 110. For example, the first underlayer 115 may have a thickness up to approximately 20 nm, up to approximately 30 nm, or up to approximately 50 nm. The combined thickness of the first underlayer 115 and the second underlayer 110 may be greater than a thickness of the photoresist 120. Though, in other embodiments, the photoresist 120 may be thicker than one or both of the first underlayer 115 and the second underlayer 110.

In an embodiment, the photoresist 120 may be any suitable photoresist material. In one instance, the photoresist 120 is any suitable CAR material. The photoresist 120 may be sensitive to EUV radiation, DUV radiation, or UV radiation.

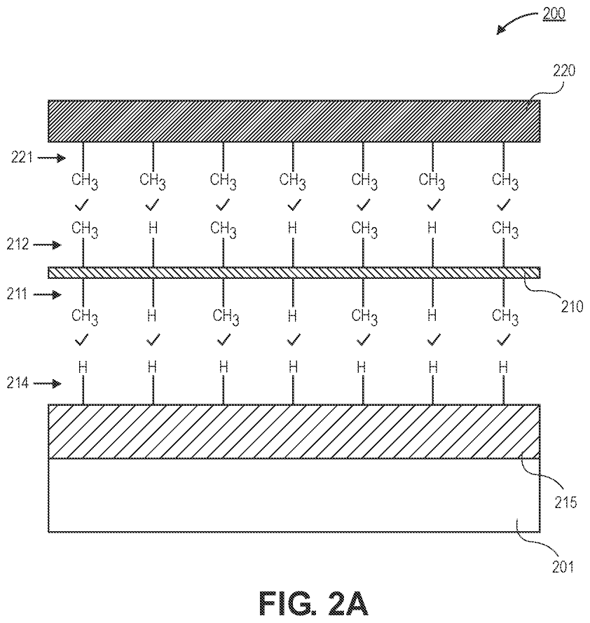

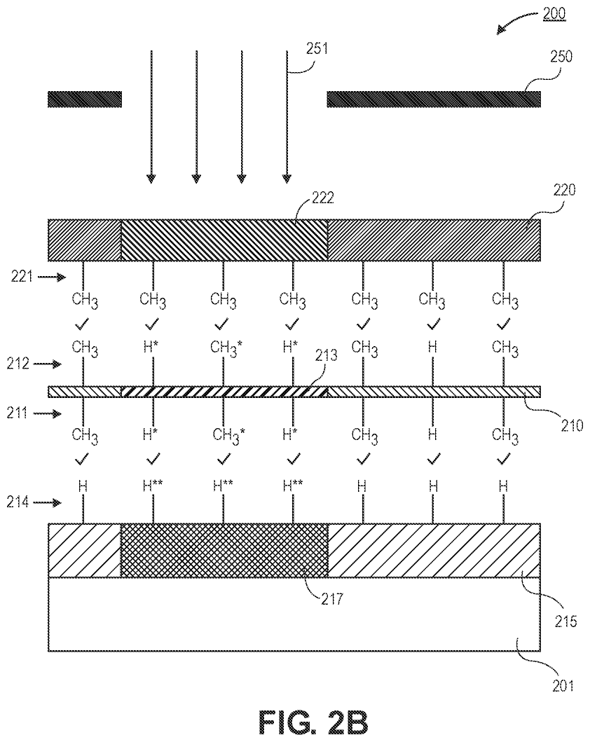

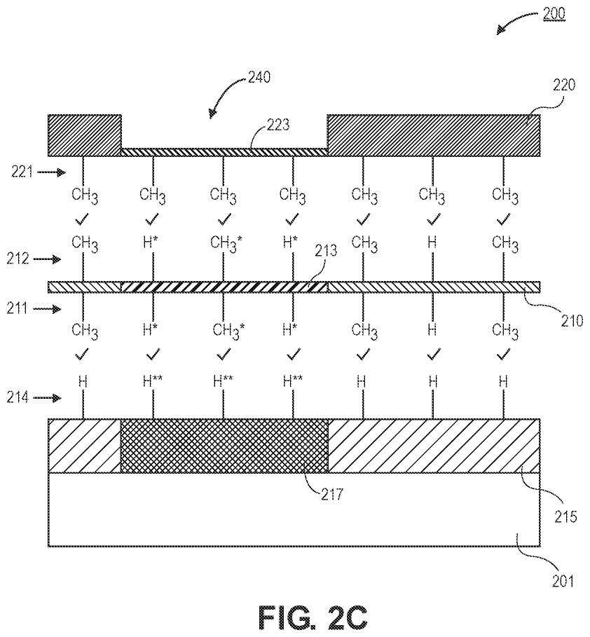

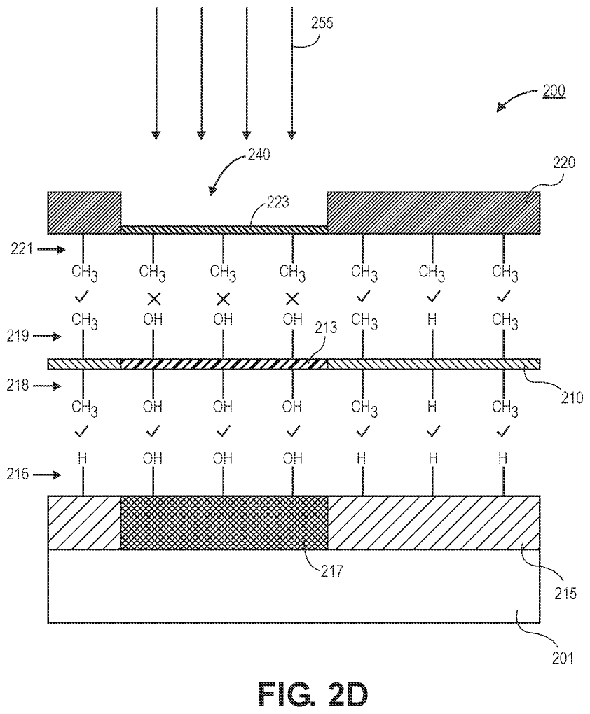

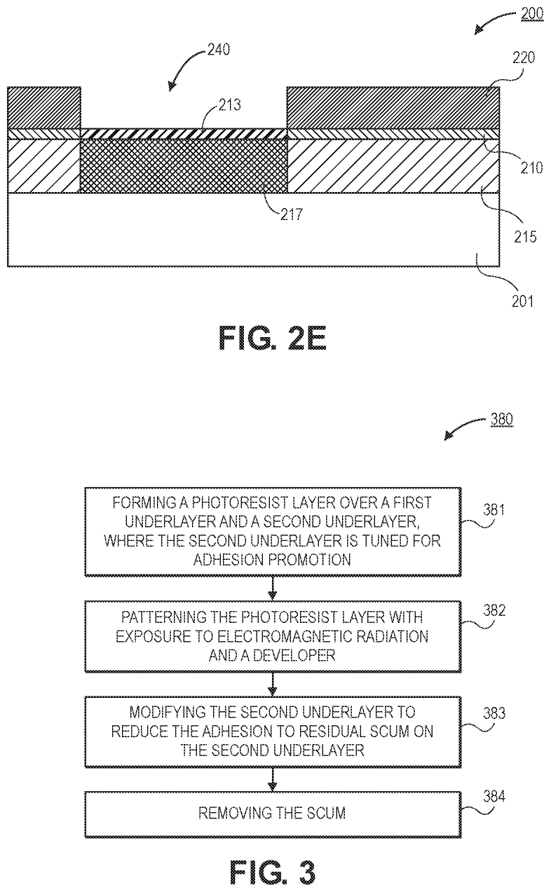

Referring now to FIGS. 2A-2E, a series of cross-sectional illustrations depicting a process for patterning a photoresist 220 is shown, in accordance with an embodiment. In the illustrated embodiments, the layers are separated from each other in order to more clearly illustrate the bonding chemistry between layers (e.g., the dangling bonds at the surface of various layers). It is to be appreciated that the different layers are, in reality, in contact with each other with adhesion strength provided by the chemical bonds.

Referring now to FIG. 2A, a cross-sectional illustration of a device 200 is shown, in accordance with an embodiment. In an embodiment, the device 200 may comprise a substrate 201. The substrate 201 may be a material to be patterned (e.g., semiconductor, metal, dielectric, insulator, etc.). The substrate 201 may also include some pattern transfer layers (e.g., hardmasks, ARCs, etc.)

In an embodiment, the substrate 201 may be covered by a first underlayer 215. The first underlayer 215 may include a material that has a hydrophobic surface. For example, dangling bonds 214 may include H or the like. While dangling bonds of only H are shown in FIG. 2A, in some embodiments, CH₃ bonds may also be present at the surface of the first underlayer 215. In an embodiment, the first underlayer 215 may also comprise Si—H bonds, Si—CH₃ bonds, B—H bonds, and the like. The bonds may be characterized as being hydrophobic.

In an embodiment, a second underlayer 210 may be provided over the first underlayer 215. The second underlayer 210 may have bonds 211 between the first underlayer 215 and the second underlayer 210. As shown, the bonds 211 may include H bonds and CH₃ bonds. The bonds 211 may have the same polarity as the bonds 214 on the first underlayer. For example, the bonds 211 may be hydrophobic in some embodiments. Due to the matching hydrophobicity in the bonds 211 and the bonds 214, the first underlayer 215 and the second underlayer 210 have a strong adhesion to each other, as indicated by the checkmarks between the bonds 211 and the bonds 214.

In an embodiment, the second underlayer 210 may be a relatively thin layer. For example, the second underlayer 210 may have a thickness up to approximately 10 nm, up to approximately 5 nm, or up to approximately 2 nm. The second underlayer 210 may also be a porous material. Due to the thin and porous nature of the second underlayer 210, the surface condition of the first underlayer 215 may be transmitted through the second underlayer 210. That is, when the first underlayer 210 has bonds 214 that are hydrophobic in nature, the second underlayer 215 will have bonds 212 that are also hydrophobic in nature. Similarly, as the bonds 214 transform into hydrophilic, the bonds 212 will also change to hydrophilic.

In this manner, the combination of the first underlayer 215 and the second underlayer 210 can be used in order to provide a patterning stack that enables high adhesion to the photoresist 220 at one point in time, and a low adhesion to the photoresist 220 at a second moment in time. Particularly, the bonds 212 shown in FIG. 2A are hydrophobic in nature (e.g., CH₃ and H), and strongly bond with the hydrophobic bonds 221 (e.g., CH₃) of the photoresist 220.

The double underlayer structure is particularly beneficial since it allows for tuning the patterning stack for both adhesion and scum removal. The second underlayer 210 that directly contacts the photoresist 220 can be specifically tuned for adhesion strength, whereas the first underlayer 215 can be a material that can readily switch between being hydrophobic and hydrophilic. Since the second underlayer 210 is relatively thin and porous, the change in the first underlayer 215 readily modifies the surface condition of the overlying second underlayer 210. In this way, the adhesion to residual scum after developing the photoresist can be decreased, and the scum is easily removed.

It is to be appreciated that the formation of a dual underlayer architecture can be enabled through the use of dry deposition processes. For example, the first underlayer 215 and the second underlayer 210 may both be formed with a chemical vapor deposition (CVD) process, an atomic layer deposition (ALD) process, or the like. In an embodiment, the photoresist 220 may also be formed with a dry deposition process. The first underlayer 215, the second underlayer 210, and the photoresist 220 may be formed in a single deposition chamber in some embodiments.

In an embodiment, the photoresist 220 may be any suitable photosensitive material used in semiconductor manufacturing. For example, the photoresist 220 may be any other suitable CAR material. The photoresist 220 may be sensitive to either EUV, DUV, or UV electromagnetic radiation. In some embodiments, the electromagnetic radiation may alter a chemistry of the photoresist 220. In some instances, exposure to electromagnetic radiation may also alter the chemistry of one or both of the first underlayer 215 and the second underlayer 210.

Referring now to FIG. 2B, a cross-sectional illustration of the device 200 is shown, in accordance with an embodiment. As shown, electromagnetic radiation 251 passes through a mask 250 in order to expose a portion of the photoresist 220. As indicated by the different shading, the exposed region 222 may have a chemical makeup that is different than the chemical makeup of the unexposed regions of the photoresist 220. For example, the exposed regions 222 may be more highly cross-linked than the unexposed regions. In the embodiment shown, a mask 250 with an opening is used to selectively expose regions of the photoresist 220. However, it is to be appreciated that the electromagnetic radiation may alternatively be reflected towards selected regions of the photoresist 220.

In an embodiment, the first underlayer 215 and the second underlayer 210 may also be altered by the exposure to electromagnetic radiation 251. For example, exposed regions 213 may be provided in the second underlayer 210, and exposed regions 217 may be provided in the first underlayer 215. While shown as being reactive to the electromagnetic radiation 251, it is to be appreciated that one or both of the first underlayer 215 and the second underlayer 210 may not be reactive to the electromagnetic radiation 251.

In an embodiment, the exposure to the electromagnetic radiation may alter the bond layers 214, 211, and 212. As indicated in FIG. 2B, the exposed portions of the bonds are modified with a *. The * indicates that the bond has increased energy. This further improves the subsequent reaction in order to convert hydrophobic bonds to hydrophilic bonds, as will be described in greater detail below.

Referring now to FIG. 2C, a cross-sectional illustration of the device 200 after a developing process is shown, in accordance with an embodiment. In an embodiment, the developing process may result in the removal of substantially all of the exposed region 222 of the photoresist 220. However, a scum 223 or other residual portion of the photoresist 220 may remain in the opening 240. As indicated by the checkmarks between the bonds 221 and the bonds 212, the scum 223 remains strongly attached to the second underlayer 210. It is difficult to remove the scum 223 since there is a strong adhesion between the scum 223 and the second underlayer 210. As such, pattern transfer into the underlying layers would be sub-optimal. The developing process may be a dry develop process or a developing process with a liquid developing chemistry.

Referring now to FIG. 2D, a cross-sectional illustration of the device 200 during a treatment is shown, in accordance with an embodiment. The treatment may be exposure to an alkaline solution 255. The alkaline solution 255 may contain H₂O or other oxygen containing chemicals. The alkaline solution 255 may react with the first underlayer 215. The first underlayer 215 may be easily convertible so that the exposed regions 217 of the bond layer 216 convert to OH bonds. Similarly, bond layer 218 may convert to OH bonds. Since bond layer 216 and 218 have the same bond type (i.e., hydrophilic), there is a strong bond between the first underlayer 215 and the second underlayer 210, as indicated by the checkmarks.

Similarly, the bond layer 219 over the second underlayer 210 may be converted to a hydrophilic bond type. The bond layer 219 may be converted by exposure to the alkaline solution 255 and/or by the change to bond layers 216 and 218. The propagation of the hydrophilic type bond through the second underlayer 210 is enabled due to the small thickness of the second underlayer 210 and the porous nature of the second underlayer 210.

As shown, the bond layer 219 no longer has a strong bond with bond layer 221 of the scum 223, as indicated by the X marks between the two. The weak bond is made since the scum 223 has a hydrophobic nature (e.g., CH₃ bonds), and the second underlayer 210 has a hydrophilic nature (e.g., OH bonds). Since the adhesion between the two layers is decreased, the scum 223 can now be removed more easily.

Referring now to FIG. 2E, a cross-sectional illustration of the device 200 after the scum 223 is removed is shown, in accordance with an embodiment. In the illustrated embodiment, the various layers are now shown directly in contact with each other without the illustration of the bond layers. However, it is to be appreciated that the bond layers shown in FIG. 2D are still present, but are omitted for simplicity. As shown, the photoresist 220 now has a clean opening 240 in order to expose the regions 217 and 213 of the first underlayer 215 and the second underlayer 210, respectively. After the scum 223 is removed, the pattern of the opening 240 can be transferred into the underlayers 210 and 215, as well as into the substrate 201.

Referring now to FIG. 3, a process flow diagram of a process 380 for scum removal is shown, in accordance with an embodiment. The process 380 shown in FIG. 3 may be substantially similar to the process described above with respect to FIGS. 2A-2E.

In an embodiment, the process 380 may begin with operation 381, which includes forming a photoresist layer over a first underlayer and a second underlayer. In an embodiment, the second underlayer is tuned for adhesion promotion with the photoresist layer. For example, the photoresist layer and the second underlayer may both have hydrophobic dangling bonds. In an embodiment, the second underlayer may have a small thickness (e.g., up to approximately 10 nm, up to approximately 5 nm, or up to approximately 2 nm). The second underlayer may also be porous. As such, surface properties of the underlying first underlayer may be propagated through the second underlayer.

In an embodiment, the process 380 may continue with operation 381, which includes patterning the photoresist layer with exposure to electromagnetic radiation and a developer. In an embodiment, the electromagnetic radiation may be EUV radiation, DUV radiation, UV radiation, or the like. The developing process may be a liquid developing process or a dry developing process. In an embodiment, the developing process may result in residual scum being provided at the bottom of the opening through the photoresist layer.

In an embodiment, the process 380 may continue with operation 383, which includes modifying the second underlayer to reduce the adhesion to residual scum on the second underlayer. In an embodiment, the modifying may be a treatment. The treatment may be the exposure of the first underlayer and the second underlayer to an alkaline solution. The first underlayer may readily react with the alkaline solution to form OH bonds. The surface chemistry of the first underlayer may propagate through the second underlayer due to the thin and porous nature of the second underlayer. In other embodiments, the alkaline solution may directly alter the chemistry of the bonds on the second underlayer. The modification results in the surface chemistry of the second underlayer being transformed from hydrophobic to hydrophilic. As such, the scum (which is hydrophobic) now has a weaker bond to the second underlayer.

In an embodiment, the process 380 may continue with operation 384, which includes removing the scum from the second underlayer. Since the adhesion between the scum and the second underlayer is reduced, the scum can be removed more easily. For example, a rinsing process or the like may be used to remove the scum. After removal of the scum, the pattern in the photoresist layer can be transferred into the underlayers and an underlying substrate.

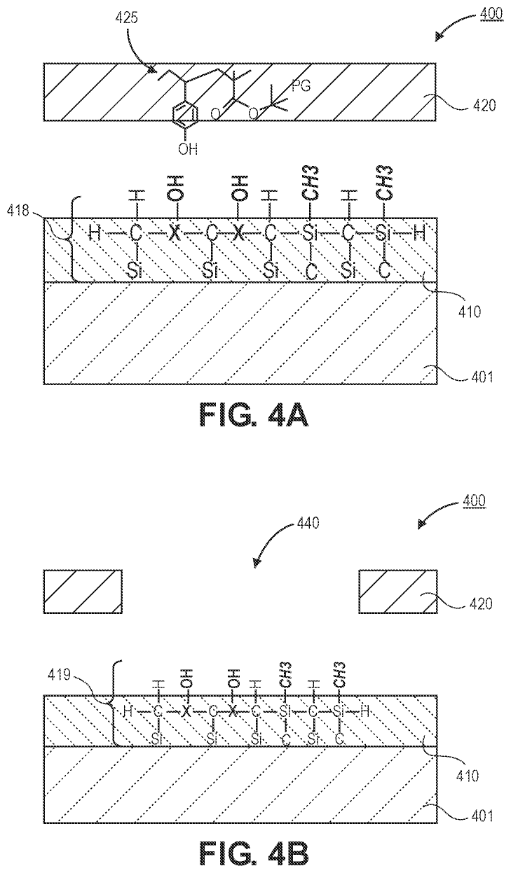

Referring now to FIGS. 4A and 4B, a pair of cross-sectional schematic illustrations of a device 400 that includes a treatment of the underlayer in order to remove scum is shown, in accordance with an embodiment.

Referring now to FIG. 4A, a cross-sectional illustration of a device 400 is shown. The device 400 may include a substrate 401. The substrate 401 may be similar to any of the substrate architectures described in greater detail above. In an embodiment, an underlayer 410 may be provided over the substrate 401. A photoresist 420 may be provided over the underlayer 410. While shown as being spaced away from the underlayer 410, it is to be appreciated that the photoresist 420 may be directly on the underlayer 410. The spaced apart relationship is shown in order to illustrate the presence of the bonding chemistry 418.

In an embodiment, the underlayer 410 may have bonding chemistry 418 that includes an amorphous SiC:H composition. The SiC:H composition may be doped with one or more doping atoms. The doping atoms may include Si, Ge, B, P, or the like. The doping elements are selected to easily react with water in an alkaline solution to form OH bonds. In FIG. 4A, the doping atoms are represented by an X in the bonding chemistry 418. As shown, the bonding chemistry includes H bonds and CH₃ bonds that provide the underlayer 410 with a hydrophobic surface. The bonding chemistry 425 of the photoresist may be an organic compound that also results in the formation of a hydrophobic surface. The matching hydrophobic surfaces enable a strong adhesion force between the underlayer 410 and the photoresist 420.

Referring now to FIG. 4B, a cross-sectional illustration of the device 400 after exposure, developing, and treating is shown, in accordance with an embodiment. The exposure and developing may result in the formation of an opening 440 through the photoresist 420. Residual scum may be removed from the opening 440 by using a treatment that converts the exposed portions of the underlayer into a surface that is hydrophilic. Particularly, an alkaline solution is applied, and the water easily reacts with the dopants to form OH bonds at the surface of the underlayer. Since the surface is converted to a hydrophilic surface, the underlayer 410 is no longer strongly attached to the scum. This allows for the scum to be easily removed (e.g., with a rinsing process).

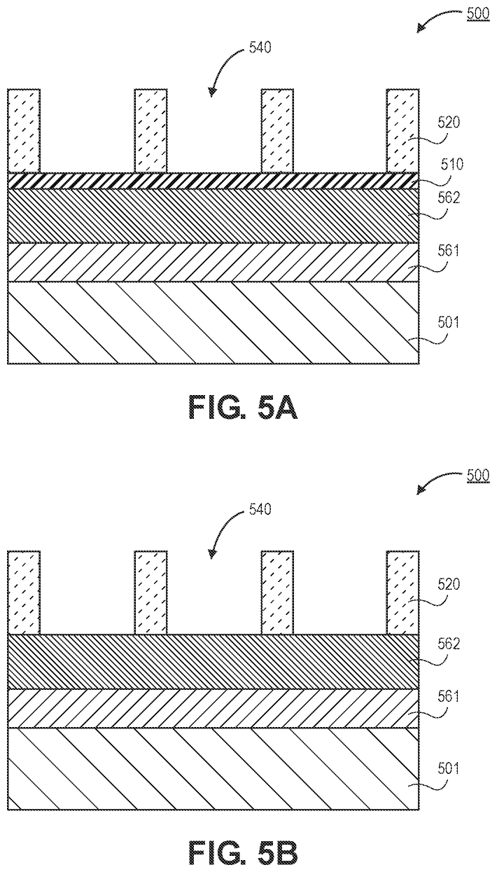

Referring now to FIGS. 5A and 5B, a pair of cross-sectional illustrations depicting patterning stacks for devices 500 is shown, in accordance with a pair of embodiments. In the embodiment shown in FIG. 5A, the device 500 comprises a substrate 501 with a stack 561 and 562. Substrate 501 may be similar to any of the substrates described in greater detail above. In an embodiment, a stack 561 and 562 may comprise any suitable materials. Particularly, layer 562 may be a low absorption layer. The low absorption layer 562 may comprise SiCH and have C(H) bonds. The chemistry of the low absorption layer 562 may be chosen in order to minimize absorption of EUV radiation.

In an embodiment, an adhesion layer 510 may be provided over the low absorption layer 562. The adhesion layer 510 may have a thickness up to approximately 10 nm, up to approximately 5 nm, or up to approximately 2 nm. In an embodiment, the adhesion layer 510 is a hydrophobic material that preferentially bonds to the overlying photoresist layer 520. The adhesion layer 510 may include SiCH, HMDS, SiOC, carbon, and the like. The surface of the adhesion layer 510 may comprise H bonds or CH₃ bonds. The photoresist layer 520 may have openings 540. The photoresist layer 520 may also have a hydrophobic surface to promote bonding to the adhesion layer 510.

Referring now to FIG. 5B, a cross-sectional illustration of the device 500 without an adhesion layer 510 is shown, in accordance with an embodiment. In an embodiment, the adhesion layer 510 may be removed when the low absorption layer 562 provides sufficient adhesion strength with the overlying photoresist layer 520.

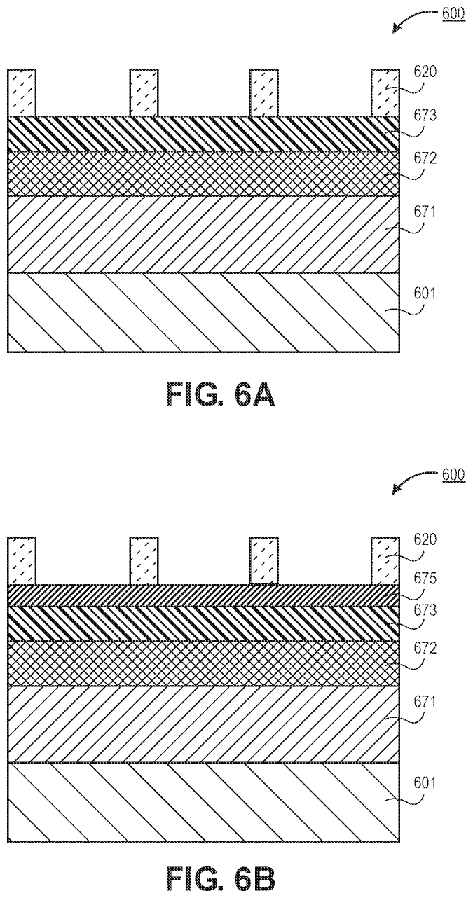

Referring now to FIGS. 6A and 6B, a pair of cross-sectional illustrations depicting patterning stacks is shown, in accordance with alternative embodiments. Embodiments illustrated in FIGS. 6A and 6B may utilize any of the adhesion and release properties or systems described in greater detail herein. That is, embodiments may allow for an initial strong adhesion between the photoresist layer that is followed by a reduction in adhesion strength in order to allow for improved scum removal.

Referring now to FIG. 6A, a cross-sectional illustration of a device 600 is shown, in accordance with an embodiment. In an embodiment, the device 600 may comprise a substrate 601. The substrate 601 may comprise a layer that is to be patterned using a lithography process. The substrate 601 may comprise a material that is typically patterned for the formation of structures in a semiconductor device, For example, the substrate 601 may comprise a semiconductor material (e.g., silicon), a metal layer, a dielectric layer, or an insulating layer. In some embodiments, the substrate 601 may also comprise layers that aid in the transfer of a pattern into the substrate 601. For example, the additional layers may include hardmask layers, ARCs, and the like.

In an embodiment, a patterning stack may be provided over the substrate 601. The patterning stack may include a plurality of different layers. For example, the patterning stack may comprise a first layer 671, a second layer 672, and a third layer 673. In an embodiment, the first layer 671 may comprise one or more of silicon, oxygen, hydrogen, nitrogen, and carbon. In an embodiment, the second layer 672 may comprise one or more of silicon, amorphous silicon, oxygen, hydrogen, and nitrogen. In an embodiment, the third layer 673 may comprises at least carbon. For example, the carbon may be a CVD carbon layer, an ALD carbon layer, or the like. In some embodiments, implanted species (e.g., silicon, germanium, boron, phosphorous, iodine, and/or hydrogen) may be implanted into one or more of the layers 671-673 in order to alter different properties such as adhesion strength, chemical reactivity, and the like. A photoresist layer 620 may be provided over the patterning stack. The photoresist layer 620 may be a metal-oxide resist (MOR) or a chemically amplified resist (CAR).

In a particular embodiment, the device 600 may comprise a stack with the following material layers. In an embodiment, the first layer 671 may comprise an oxide, such as silicon oxide. The first layer 671 may have a thickness up to approximately 100 nm. For example, the first layer 671 may have a thickness of approximately 50 nm or less. In an embodiment, the second layer 672 may comprise an amorphous silicon layer. The amorphous silicon layer may be formed with any suitable deposition process, such as plasma enhanced CVD (PECVD). The second layer 672 may have a thickness up to approximately 50 nm in some embodiments. In a particular embodiment, the second layer 672 may have a thickness that is approximately 20 nm or less. In an embodiment, the third layer 673 may comprise a layer of carbon, such as a CVD carbon layer. The third layer 673 may have a thickness that is up to approximately 50 nm. For example, the third layer 673 may have a thickness of approximately 30 nm or less.

In yet another embodiment, the patterning stack may have the following material layers. In an embodiment, the first layer 671 may comprise silicon, oxygen, and nitrogen. For example, the first layer 671 may comprise SiON in some embodiments. The second layer 672 may comprise silicon, oxygen, and hydrogen. In an embodiment, the third layer 673 may comprise the same elements as the first layer 671. In the particular embodiment described here, the third layer 673 may comprise silicon, oxygen, and nitrogen (e.g., SiON). The first layer 671, the second layer 672, and the third layer 673 may have thicknesses that are less than approximately 1,000 Å. For example, the first layer 671 may have a thickness up to approximately 350 Å, the second layer 672 may have a thickness up to approximately 450 Å, and the third layer 673 may have a thickness up to approximately 250 Å.

In yet another embodiment, the patterning stack may be structured as follows. The first layer 671 may comprise an oxide, such as one including silicon and oxygen (e.g., SiO₂). The second layer 672 may comprise silicon. For example, the second layer 672 may comprise an amorphous silicon layer. In an embodiment, the third layer 673 may be any suitable underlayer material. For example, the third layer may comprise silicon, carbon, and hydrogen (e.g., SiCH), HMDS, silicon, oxygen, and carbon (SiOC), or the like. The first layer 671, the second layer 672, and the third layer 673 may each have a thickness up to approximately 500 nm.

In yet another embodiment, the patterning stack may comprise an additional interface layer (not shown) between the substrate 601 and the first layer 671. For example, the interface layer may be considered an adhesion layer, a hardmask layer, or the like. In some embodiments, the interface layer may include titanium and nitrogen. For example, the interface layer may comprise TiN in some embodiments.

Referring now to FIG. 6B, a cross-sectional illustration of a device 600 is shown, in accordance with an additional embodiment. The device 600 in FIG. 6B may be substantially similar to the device 600 in FIG. 6A, with the addition of an antireflective coating (ARC) 675 over the third layer 673. The ARC 675 may be any suitable ARC material or materials. For example, the ARC may comprise one or both of a dielectric ARC (DARC) or a bottom layer ARC (BARC). That is, the ARC 675 may include at least two distinct layers in some embodiments. The ARC 675 may have a thickness up to approximately 40 nm in some embodiments. In a particular embodiment, the ARC 675 may have a thickness up to approximately 20 nm.

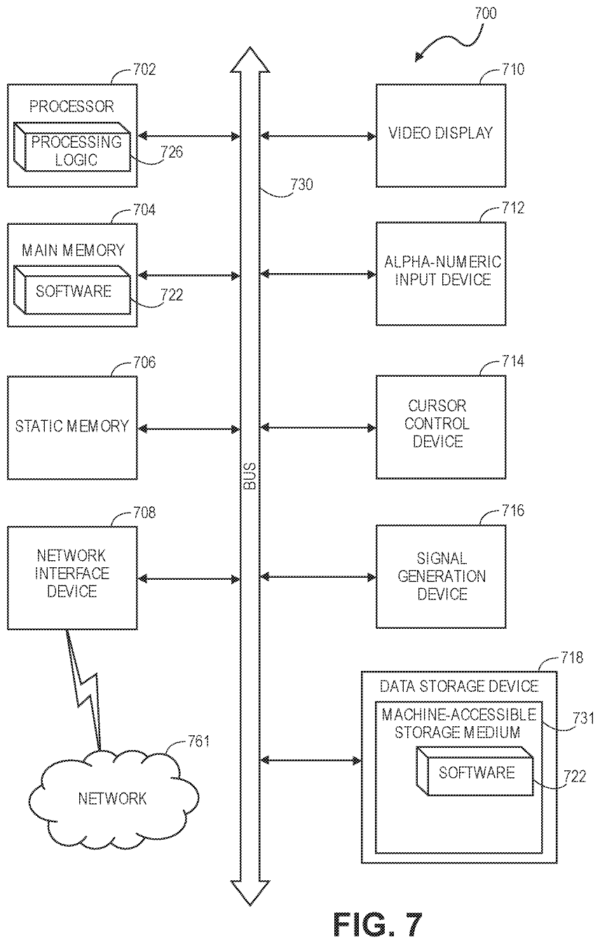

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet.

The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), MRAM, etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of providing a photoresist stack with a first underlayer and a second underlayer. In an embodiment, the second underlayer is less than 5 nm thick and is tuned for high adhesion strength with the overlying photoresist layer. After patterning, the first underlayer and the second underlayer are treated with an alkaline solution containing water. The solution converts hydrophobic surfaces of the first underlayer and the second underlayer into hydrophilic surfaces which have a reduced bond strength with the photoresist layer. Any scum can then be easily rinsed from the stack.

Thus, methods for forming a photoresist stack with high adhesion and improved descumming have been disclosed.

What is claimed is:

1. A method of developing a patterning stack, comprising:
providing a patterning stack, wherein the patterning stack comprises an underlayer and a photoresist over the underlayer, wherein the underlayer has a first adhesion strength with the photoresist;
exposing and developing the photoresist with electromagnetic radiation and a developer, wherein scum remains on a surface of the underlayer;
treating the underlayer so that the underlayer has a second adhesion strength with the scum; and
removing the scum.

2. The method of claim 1, wherein the underlayer is hydrophobic before the treatment and hydrophilic after the treatment.

3. The method of claim 1, wherein the underlayer comprises H terminations and CH₃ terminations before the treatment.

4. The method of claim 3, wherein the underlayer comprises OH terminations after the treatment.

5. The method of claim 1, wherein the treatment is exposure to an alkaline solution.

6. The method of claim 1, wherein the underlayer has a thickness that is up to approximately 5 nm.

7. The method of claim 6, further comprising:
a second underlayer below the underlayer.

8. The method of claim 6, wherein the second underlayer is more reactive to the treatment than the underlayer.

9. The method of claim 1, wherein underlayer comprises an amorphous SiC:H material.

10. The method of claim 9, wherein the SiC:H is doped with one or more of Ge, B, and P.

11. The method of claim 10, wherein the one or more of Ge, B, and P more readily react with the treatment to form an OH bond compared to the SiC:H.

12. A method of patterning a substrate, comprising:
providing a patterning stack over the substrate, wherein the patterning stack comprises:
a first underlayer;
a second underlayer over the first underlayer; and
a photoresist over the second underlayer;
exposing the patterning stack to electromagnetic radiation;
developing the photoresist in the patterning stack;
modifying the second underlayer so that an adhesion strength to the photoresist is decreased; and
removing any scum over the second underlayer.

13. The method of claim 12, wherein the second underlayer has a thickness that is up to approximately 5 nm.

14. The method of claim 13, wherein the second underlayer is porous.

15. The method of claim 12, wherein the second underlayer has a hydrophobic surface before modification and a hydrophilic surface after modification.

16. The method of claim 12, wherein modifying the second underlayer comprises exposing the first underlayer and the second underlayer to an alkaline solution.

17. The method of claim 12, wherein the photoresist is a CAR.

18. A patterning stack, comprising:
a first underlayer;
a second underlayer over the first underlayer, and wherein the second underlayer has a hydrophobic surface; and
a photoresist over the second underlayer, wherein the photoresist has a hydrophobic surface.

19. The patterning stack of claim 18, wherein the second underlayer is converted to a hydrophilic surface after exposure to an alkaline solution.

20. A patterning stack, comprising:
a first layer, wherein the first layer comprises one or more of silicon, oxygen, hydrogen, nitrogen, and carbon;
a second layer over the first layer, wherein the second layer comprises one or more of silicon, amorphous silicon, oxygen, hydrogen, and nitrogen;
a third layer over the second layer, wherein the third layer comprises carbon; and
a photoresist over the third layer, wherein the photoresist is a metal-oxide resist (MOR) or a chemically amplified resist (CAR).
